(19) United States
(12) Patent Application Publication
(10) Pub. No.: US 2026/0105967 A1
(43) Pub. Date: Apr. 16, 2026

(54) MEMORY DEVICE AND OPERATION METHOD THEROF

(71) Applicant: MACRONIX International Co., Ltd., Hsinchu (TW)

(72) Inventors: Wei-Han Chen, Tainan City (TW); E-Yuan Chang, Hsinchu County (TW); Yih-Shan Yang, Hsinchu City (TW)

(73) Assignee: MACRONIX International Co., Ltd., Hsinchu (TW)

(21) Appl. No.: 19/050,126

(22) Filed: Feb. 11, 2025

Related U.S. Application Data
(60) Provisional application No. 63/707,207, filed on Oct. 15, 2024.

(51) Int. Cl. G11C 16/24

(52) U.S. Cl. CPC G11C 16/24

(57) ABSTRACT

A memory device may be a 3D NAND flash memory circuit, and provides a high-capacity storage medium with favorable performance. The memory device includes a plurality of page buffers and a plurality of first switches. The page buffers are coupled in series. The first switches respectively correspond to the page buffers, wherein each of the first switches is coupled to a sensing node of corresponding page buffer. Each of the first switches receives a reference voltage and provides a source current to the sensing node of corresponding page buffer after a data sensing period.

### CROSS-REFERENCE TO RELATED APPLICATION

This application claims the priority benefit of U.S. provisional application Ser. No. 63/707,207, filed on Oct. 15, 2024. The entirety of the above-mentioned patent application is hereby incorporated by reference herein and made a part of this specification.

### BACKGROUND

### Technical Field

The present disclosure pertains to a memory device and an operating method thereof, and more specifically to a memory device and an operating method thereof designed to mitigate data sensing errors.

### Description of Related Art

In a memory device, when the data sensing operation of the page buffer is performed, the system applies sensed data to the sensing node of the page buffer. The sensing node of the page buffer receives a clock signal through a capacitor. During the data sensing process, the clock signal is pulled down, consequently causing a corresponding reduction in voltage on the sensing node of the page buffer. As a result, data on the sensing node of the page buffer may be subject to errors. Furthermore, in multiple page buffers coupled in series, the sensing node of unselected page buffer is in a floating state. Consequently, the clock signal pull-down action might cause the voltage on the sensing node of unselected page buffer to be pulled down to a negative voltage. This phenomenon might lead to a conductive state between the sensing node corresponding to the selected word line and the sensing node corresponding to the unselected word line in adjacent page buffers, thereby compromising the accuracy of the sensed data.

### SUMMARY

The present disclosure provides a memory device and an operational method thereof, which prevents the occurrence of sensing data errors in the page buffer.

The memory device of the present disclosure includes multiple page buffers and multiple first switches. The page buffers are coupled in series. The first switches respectively correspond to the page buffers, wherein each of the first switches is coupled to the sensing node of the corresponding page buffer. Each of the first switches receives a reference voltage and provides a source current to the sensing node of the corresponding page buffer after a data sensing period.

The operation method of the memory device in the present disclosure includes: providing multiple page buffers coupled in series; configuring multiple first switches to respectively correspond to the page buffers, such that each of the first switches is coupled to the sensing node of the corresponding page buffer; and enabling each of the first switches to provide a source current to the sensing node of the corresponding page buffer according to the received reference voltage after a data sensing period.

Based on the above, the present disclosure sets one of the first switches on the sensing node of each of the page buffers. Moreover, by enabling the first switch to provide the source current to the sensing node of the corresponding page buffer after the data sensing period, and thereby, when a voltage of a clock signal reducing, charging the sensing node which is varied to a negative voltage to avoid to mis-activate transistor adjacent to the sensing node. In this way, the accuracy of the voltage on the sensing node of the page buffer may be improved, and the accuracy of the data stored in the page buffer may be improved.

### BRIEF DESCRIPTION OF THE DRAWINGS

FIG. 1 illustrates a schematic diagram of a memory device according to an embodiment of the present disclosure.

FIG. 2 illustrates a schematic diagram of a memory device according to an embodiment of the present disclosure.

FIG. 3 illustrates a schematic diagram of a memory device according to another embodiment of the present disclosure.

FIG. 4 illustrates an operational waveform diagram of the memory device 300 according to an embodiment of the present disclosure.

FIG. 5 illustrates a flow chart of a programmed verification operation according to an embodiment of the present disclosure.

FIG. 6 illustrates the operation method of the memory device in an embodiment of the present disclosure.

### DESCRIPTION OF THE EMBODIMENTS

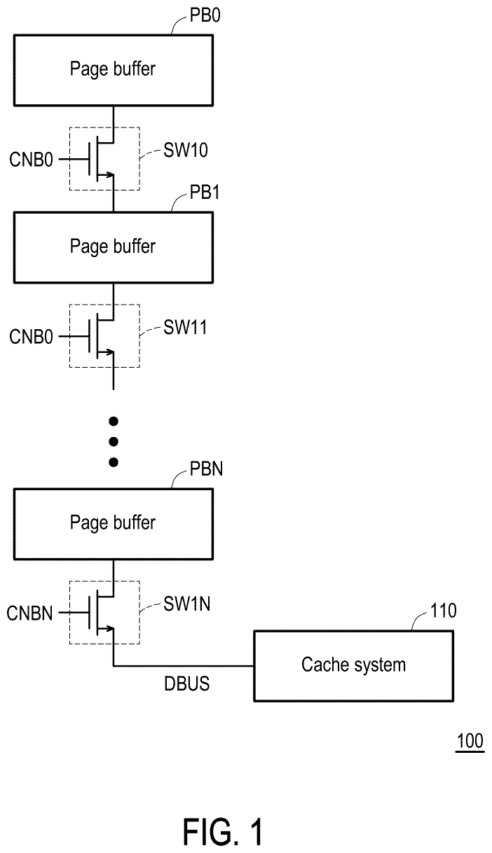

Please refer to FIG. 1, which illustrates a schematic diagram of a memory device according to an embodiment of the present disclosure. The memory device 100 includes multiple page buffers PB0 to PBN. The page buffers PB0-PBN coupled in series through switches SW10 to SW1N. Specifically, the switch SW10 is configured to connect adjacent page buffers PB0 and PB1, the switch SW11 is configured to connect adjacent page buffers PB1 and PB2, and so forth for the remaining switches. The final stage page buffer PBN may be coupled to a data bus DBUS through the switch SWN, and further coupled to a cache system 110 through the data bus DBUS. In this embodiment, the switches SW10 to SW1N may all be transistor switches, and are respectively controlled by the control signals CNB0 to CNBN.

In the present embodiment, the page buffers PB0 to PBN and the cache system 110 may be connected in series through the switches SW10 to SW1N, thereby performing data exchange operations between the page buffers PB0 to PBN and the cache system 110. Furthermore, the switches SW10 to SW1N may be respectively coupled to the sensing nodes within the page buffers PB0 to PBN.

Whereas each of the switches SW10 to SW1N has a certain amount of parasitic capacitance, therefore, when a voltage change occurs on the sensing node of any one of the page buffers PB0 to PBN, due to the capacitive effect through the switches SW10 to SW1N, the voltages on each of the sensing nodes of the page buffers PB0 to PBN will be affected to some extent.

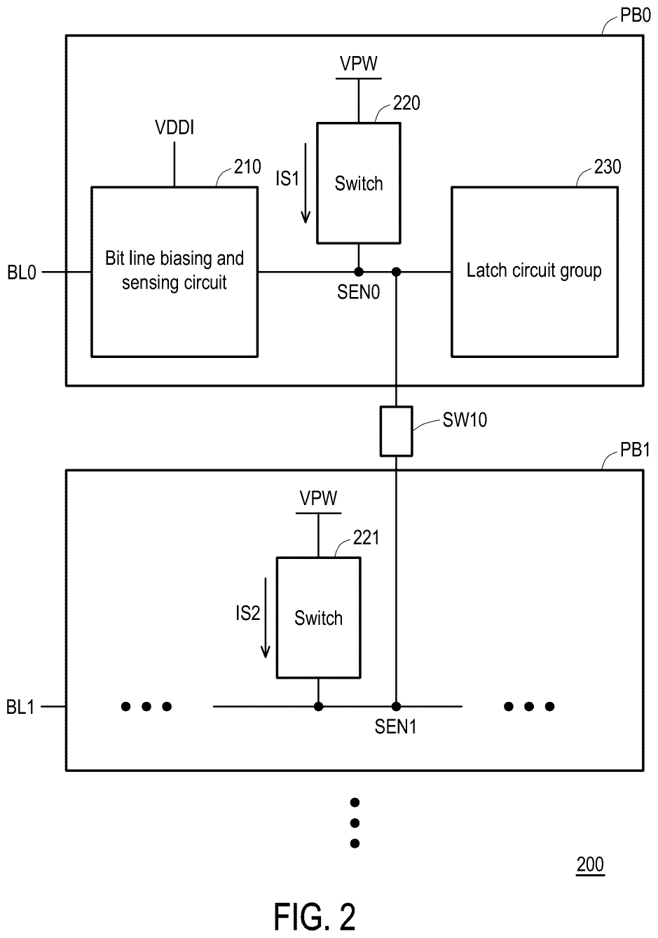

Please refer to FIG. 2, which illustrates a schematic diagram of the memory device according to an embodiment of the present disclosure. The memory device 200 includes page buffers PB0 and PB1, switches 220 and 221, and the switch SW10. The switch SW10 is configured to connect page buffers PB0 and PB1 in series. The page buffers PB0 and PB1 have similar circuit structures and are respectively coupled to bit lines BL0 and BL1. Taking the page buffer PB0 as an example, the page buffer PB0 includes a bit line biasing and sensing circuit 210 and a latch circuit group 230. The bit line biasing and sensing circuit 210, the latch circuit group 230, and the switch 220 are mutually coupled to the sensing node SEN0. The switch 220 may be disposed within the page buffer PB0. The first terminal of the switch 220 may receive the reference voltage VPW, while the second terminal of the switch 220 is coupled to the sensing node SEN. Operationally, during the operation of the page buffer PB0, following the data sensing period of the page buffer PB0, the switch 220 may provide a source current IS1 to the sensing node SEN0 of the page buffer PB0 based on the reference voltage VPW, thereby charging the sensing node SEN0. Furthermore, through the charging action of the source current IS1 on the sensing node SEN0, the voltage on the sensing node SEN0 may be compensated, thus maintaining the voltage on the sensing node SEN0 at the correct voltage value.

Furthermore, the switch SW10 is coupled between the sensing node SEN0 of page buffer PB0 and the sensing node SEN1 of the page buffer PB1. Within the page buffer PB1, the switch 221 is coupled to the sensing node SEN1 of the page buffer PB1. Similarly, the switch 221 receives the reference voltage VPW and provides the source current IS2 to the sensing node SEN1 of the page buffer PB1 based on the reference voltage VPW after the data sensing period, thereby compensating for the voltage on the sensing node SEN1.

In the present embodiment, the bit line biasing and sensing circuit 210 is coupled to the bit line BL0 and receives the power supply voltage VDDI as an operational power supply therefor. The bit line BL0 may be coupled to a memory cell. The bit line biasing and sensing circuit 210 is configured to perform a biasing operation on the bit line BL0 and may be used to conduct a data sensing operation of the stored data in the corresponding memory cell based on the voltage on the bit line BL0, and transmit the sensed data to the sensing node SEN0. The latch circuit group 230 is coupled to the sensing node SEN0. The latch circuit group 230 may include multiple latch circuits, wherein the multiple latch circuits may respectively store multiple buffer data. Each of the latch circuits may perform a data transfer operation on the sensed data on the sensing node SEN0, and transfer the sensed data from the sensing node SEN0 to each of the latch circuits to generate corresponding buffer data. Furthermore, the latch circuits may execute logical operations between the respectively stored buffer data and generate corresponding operation results.

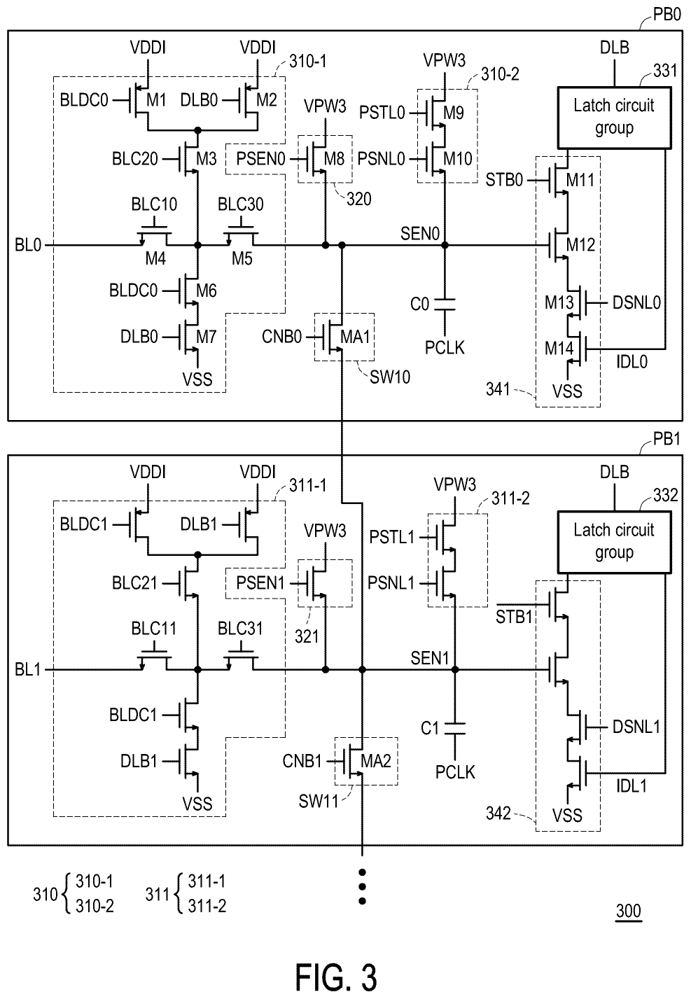

Please refer to FIG. 3, which illustrates a schematic diagram of a memory device according to another embodiment of the present disclosure. The memory device 300 includes multiple page buffers PB0 and PB1, and switches 320 and 321. The switches 320 and 321 may be respectively disposed within the page buffers PB0 and PB1, or outside the page buffers PB0 and PB1. The page buffers PB0 and PB1 may be coupled to each other through the switch SW10, while the page buffer PB1 may be coupled to the next stage of the page buffer through the switch SW11. Specifically, the switch SW10 may be coupled between the sensing node SEN0 of the page buffer PB0 and the sensing node SEN1 of the page buffer PB1. The switch SW11 may be coupled between the sensing node SEN1 of the page buffer PB1 and the sensing node of the next stage of the page buffer. In this embodiment, the switches SW10 and SW11 may be respectively constructed using transistors MA1 and MA2, and are controlled by control signals CNB0 and CNB1.

The first terminal of the switch 320 receives the reference voltage VPW3, while the second terminal of the switch 320 is coupled to the sensing node SEN0 of the page buffer PB0. The switch 320 may be a transistor switch, constructed by the transistor M9. The transistor M9 is controlled by the control voltage PSEN0, and based on the reference voltage VPW3, provides a source current to the sensing node SEN0 of the page buffer PB0 according to the control voltage PSEN0.

The page buffer PB0 includes a bit line biasing and sensing circuit 310, a capacitor C0, a latch circuit group 331, and a control circuit 341 corresponding to the latch circuit group 331. The bit line biasing and sensing circuit 310 is composed of partial circuits 310-1 and 310-2. Both partial circuits 310-1 and 310-2 are coupled to the sensing node SEN0. The first terminal of the capacitor C0 is coupled to the sensing node SEN0, while the second terminal of the capacitor C0 receives a clock signal PCLK. The control circuit 341 is coupled to the sensing node SEN0 and is coupled to the latch circuit group 331.

The partial circuit 310-1 includes multiple transistors M1 to M7. The transistors M1 and M2 are coupled in parallel and jointly receive a power supply voltage VDDI. One terminal of the transistor M3 is coupled to the transistors M1 and M2 jointly, while the other terminal of the transistor M3 is coupled to one terminal of each of the transistors M4 and M5. The other terminal of the transistor M4 is coupled to the bit line BL0, while the other terminal of the transistor M5 is coupled to the sensing node SEN0. Furthermore, the transistors M6 and M7 are connected in series between the mutual coupling terminal of the transistors M4 and M5 and the reference ground voltage VSS. The transistors M1 to M7 are respectively controlled by the control signals BLDC0, DLB0, BLC20, BLC10, BLC30, BLDC0, and DLB0. Based on the complementary conductive polarity of the transistor M1 and the transistor M6, a turned-on or cut-off states of the transistor M1 and the transistor M6 are opposite; similarly, based on the complementary conductive polarity of the transistor M2 and the transistor M7, the turned-on or cut-off states of the transistor M2 and the transistor M7 are opposite. Herein, the transistors M1 and M2 provide a pull-up path for the mutual coupling terminal of the transistors M4 and M5, while the transistors M6 and M7 provide a pull-down path for the mutual coupling terminal of the transistors M4 and M5.

Furthermore, the transistor M4 functions as a switch, and when being turned-on, the transistor M4 allows the voltage on the bit line BL0 to be transmitted to the junction between the transistors M3 and M6. The transistor M5 serves as a control switch, and when being turned-on, the transistor M5 further enables the voltage on the bit line BL0 to be transmitted to the sensing node SEN0.

Another partial circuit 310-2 includes transistors M9 and M10. The transistors M9 and M10 are coupled in series between the reference voltage VPW3 and the sensing node SEN0. The transistors M9 and M10 are respectively controlled by the control signals PSTL0 and PSNL0. When both transistors M9 and M10 are turned-on, the partial circuit 310-2 is capable of pulling up the voltage on the sensing node SEN0 based on the reference voltage VPW3.

The control circuit 341 includes transistors M11 to M14. The transistors M11 to M14 are sequentially coupled in series between the latch circuit group 331 and the reference ground voltage VSS. Specifically, the transistor M11 is controlled by the control signal STB0; the control terminal of the transistor M12 is coupled to the sensing node SEN0; the transistors M13 and M14 are respectively controlled by the control signals DSNL0 and IDL0.

The page buffer PB1 includes a bit line biasing and sensing circuit 311, a capacitor C1, a latch circuit group 332, and a control circuit 342 corresponding to the latch circuit group 332. The bit line biasing and sensing circuit 311 is composed of partial circuits 311-1 and 311-2. Both partial circuits 311-1 and 311-2 are coupled to the sensing node SEN1. The first terminal of the capacitor C1 is coupled to the sensing node SEN1, while the second terminal of the capacitor C1 receives a clock signal PCLK. The control circuit 342 is coupled to the sensing node SEN1 and is coupled to the latch circuit group 332. The partial circuit 311-1 is controlled by control signals BLDC1, DLB1, BLC21, BLC11, and BLC31. The partial circuit 311-2 is controlled by the control signals PSTL1 and PSNL1. The control circuit 342 is controlled by the control signal STB1, the voltage on the sensing node SEN1, and control signals DSNL1 and IDL1. It is noteworthy that the page buffer PB1 has a circuit architecture similar to that of the page buffer PB0, and the identical portions will not be reiterated.

In the present embodiment, the page buffer PB0 may be either an unselected buffer or a selected buffer. Taking the page buffer PB0 as a selected buffer as an example, the page buffer PB1 may be an unselected buffer. Consequently, during the programmed verification operation, the page buffer PB1 does not perform data verification, while the page buffer PB0 may execute data verification. In this embodiment, prior to entering the data sensing period of the programmed verification operation, the sensing node SEN0 of the page buffer PB0 may be pulled up to the reference voltage VPW3 through the partial circuit 310-2. Given that the page buffer PB1 is an unselected buffer, the control signal DSNL1 may make the corresponding transistor to be turned-on, thereby providing a discharge path for the sensing node SEN1.

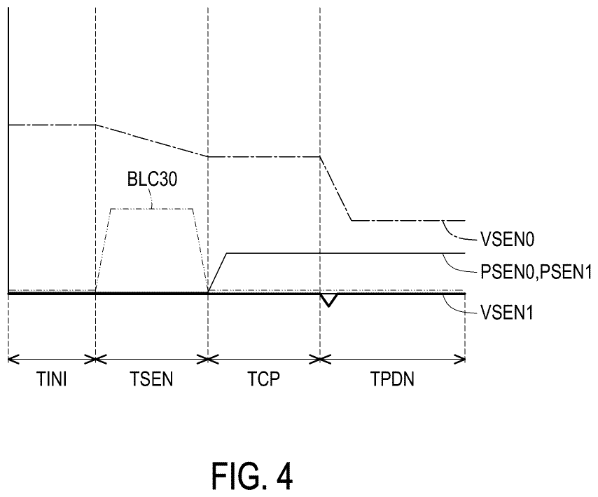

Please refer to FIG. 3 and FIG. 4 concurrently, wherein FIG. 4 illustrates the operational waveform diagram of the memory device 300 in an embodiment of the present disclosure. In this embodiment, the bit line BL0 is the selected bit line, while the bit line BL1 is the unselected bit line. Correspondingly, the page buffer PB0 is the selected buffer, whereas the page buffer PB1 is the unselected buffer. During the initial time interval TINI, the voltage VSEN0 on the sensing node SEN0 is pulled up to a relatively high voltage value, while the voltage VSEN1 on the sensing node SEN1 is maintained at a relatively low voltage value (e.g., 0 volts) through a discharge operation.

On the other hand, prior to the memory device 300 entering the data sensing period TSEN, the clock signal PCLK may be raised to the first voltage value (corresponding to logical value 1), and may subsequently enter the data sensing period TSEN.

During the data sensing period TSEN, the control signal BLC31 and BLC30 are pulled up, causing the transistor M5 to be turned-on. At this juncture, the data on the bit line BL0 may be transmitted to the sensing node SEN0 to execute the data sensing operation. Correspondingly, the voltage VSEN0 on the sensing node SEN0, which corresponds to the data on the bit line BL0, begins to decrease. Upon conclusion of the data sensing period TSEN, during the compensation period TCP, the control voltages PSEN0 and PSEN1 are both pulled up. Consequently, the switches 320 and 321 are simultaneously turned-on, and providing the source current to corresponding respective sensing nodes SEN0 and SEN1. Subsequently, during the data transfer period TPDN following the compensation period TCP, the clock signal PCLK may be pulled down from a first voltage value to a second voltage value (corresponding to logical value 0). Due to the coupling effect of the capacitors C0 and C1, the voltages VSEN0 and VSEN1 on the sensing nodes SEN0 and SEN1, respectively, exhibit a corresponding downward trend. It is noteworthy that, as the switches 320 and 321 continue to provide source current to the sensing nodes SEN0 and SEN1 respectively during this period, the voltages VSEN0 and VSEN1 on the sensing nodes SEN0 and SEN1 may effectively receive compensation. This mechanism effectively mitigates potential voltage drops of the voltages VSEN0 and VSEN1 on the sensing nodes SEN0 and SEN1, thus reducing the likelihood of erroneous data sensing due to voltage fluctuations on VSEN0 and VSEN1.

Based on the foregoing, it can be clearly ascertained that in the embodiments of the present disclosure, regardless of whether the buffer is selected or unselected, the page buffers PB0 and PB1, throughout the entire programmed verification procedure, execute compensatory actions through the source current provided by the switches 320 and 321. This may effectively prevent the sensing nodes SEN0 and SEN1 from generating the voltages VSEN0 and VSEN1 due to the coupling effect of the capacitors C0 and C1. It is noteworthy that the voltage VSEN1 on the sensing node SEN1 of the unselected buffer (e.g., page buffer PB1) may not decrease to a negative voltage due to the lowering action of the clock signal PCLK. Consequently, the turned-on state of the switch SW11 remains unaffected, thereby maintaining the normal operation of the memory device 300.

Please be advised that during the compensation period TCP and the data transfer period TPDN, the control voltages PSEN0 and PSEN1 may be substantially equal to the threshold conducting voltage Vt of the corresponding transistors (e.g., transistor M8) of the switches 320 and 321. In this embodiment, the threshold conducting voltage Vt is lower than the power supply voltage VDDI.

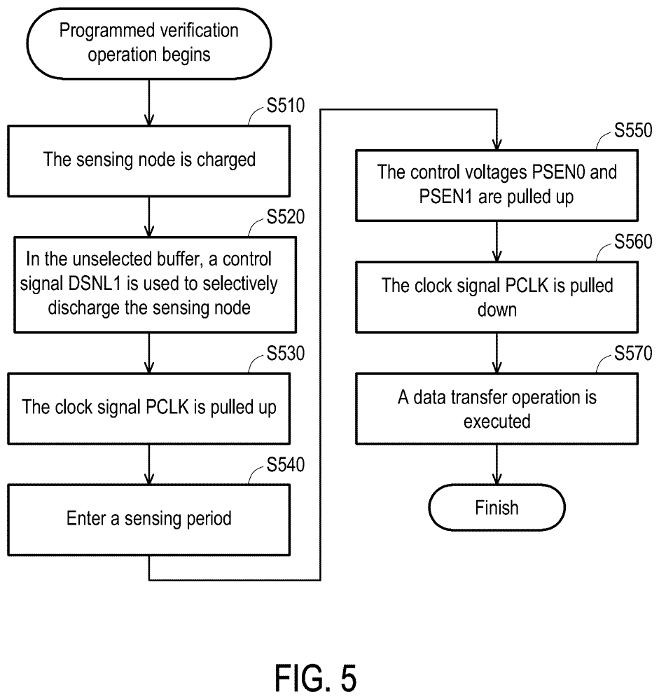

Please refer to FIG. 3 and FIG. 5 simultaneously, where FIG. 5 illustrates a flow chart of the programmed verification operation in an embodiment of the present disclosure. In step S510, the sensing nodes SEN0 and SEN1 of all of the page buffers PB0 and PB1 may be charged. In step S520, in the unselected buffer (e.g., page buffer PB1), a discharge path is generated through the control signal DSNL1 to selectively discharge the sensing node SEN1. In step S530, the clock signal PCLK may be pulled up. In step S540, a sensing period may be turned-on. Subsequently, in step S550, the control voltages PSEN0 and PSEN1 may be simultaneously pulled up, causing the switches 320 and 321 to be turned-on.

Subsequently, in step S560, the clock signal PCLK may be pulled down. In step S570, a data transfer operation may be executed, whereby the data on the sensing node SEN0 is transferred to and stored in the latch circuit group 331, thus completing this process.

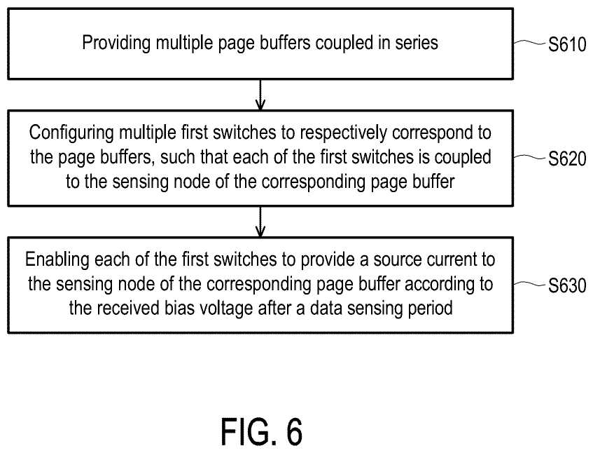

Please refer to FIG. 6, which illustrates the operation method of the memory device in an embodiment of the present disclosure. In step S610, multiple page buffers that are coupled in series are provided. In step S620, multiple first switches are configured to respectively correspond to the page buffers, such that each of the first switches is coupled to the sensing node of the corresponding page buffer. In step S630, each of the first switches is enabled to provide a source current to the sensing node of the corresponding page buffer based on the received reference voltage after the data sensing period. The implementation details of the aforementioned steps have been elaborately described in the preceding embodiments and will not be reiterated herein for the sake of brevity.

Based on the foregoing, the memory device of the present disclosure incorporates a switch on the sensing node of the page buffer. This switch is enabled to provide a source current to the sensing node of the corresponding page buffer after the sensing period of the page buffer. The purpose of this mechanism is to compensate for any potential voltage drop that might occur to the voltage on the sensing node of the page buffer following the sensing period. Consequently, this arrangement ensures the accuracy of the sensed data in the page buffer, thereby maintaining the normal operation of the memory device.

What is claimed is:

1. A memory device, comprising:
a plurality of page buffers, wherein the plurality of page buffers are coupled in series; and
a plurality of first switches, respectively corresponding to the plurality of page buffers, wherein each of the plurality of first switches is coupled to a sensing node of the corresponding page buffer,
wherein each of the plurality of first switches receives a reference voltage, and provides a source current to the sensing node of the corresponding page buffer after a data sensing period.

2. The memory device according to claim 1, further comprising:
a plurality of second switches, wherein each of the plurality of second switches is coupled between two adjacent page buffers among the plurality of page buffers.

3. The memory device according to claim 1, wherein each of the plurality of first switches is controlled by a control voltage, and each of the plurality of first switches provides the source current to charge the sensing node according to the control voltage based on the reference voltage after the data sensing period.

4. The memory device according to claim 3, wherein after the data sensing period, a voltage value of the control voltage is equal to a threshold conducting voltage value of the first switch.

5. The memory device according to claim 1, wherein the first switch of at least one unselected buffer among the plurality of page buffers provides the source current to charge the sensing node after the data sensing period to maintain a voltage on the sensing node at a reference ground voltage value.

6. The memory device according to claim 1, wherein the first switch of a selected buffer among the plurality of page buffers provides the source current to charge the sensing node after the data sensing period, in order to maintain a voltage on the sensing node at a sensed voltage value.

7. The memory device according to claim 1, wherein each of the plurality of page buffers further comprises:
a bit line biasing and sensing circuit, coupled between a bit line and the corresponding sensing node, and configured to sense data on the bit line and generate a sensed voltage on the sensing node;
a capacitor, having a first terminal coupled to the sensing node, wherein a second terminal of the capacitor receives a clock signal; and
a latch circuit group, having a plurality of latch circuits for respectively storing a plurality of buffer data.

8. The memory device according to claim 7, wherein in each of the plurality of page buffers, the bit line biasing and sensing circuit is coupled to the sensing node through a control switch, during the data sensing period, the bit line biasing and sensing circuit is coupled to the sensing node through the control switch in a conductive state.

9. The memory device according to claim 7, wherein during a compensation period following the data sensing period, the first switch of each of the plurality of page buffers begins to be turned-on, and provides the source current to the sensing node of the corresponding page buffer.

10. The memory device according to claim 9, wherein in a data transfer period following the compensation period, the clock signal is pulled down from a first voltage value to a second voltage value, thereby enabling the data to be transferred from the sensing node to the latch circuit group,
wherein during the data transfer period, the first switch of each of the plurality of page buffers remains in a conductive state.

11. The memory device according to claim 1, wherein each of the plurality of first switches is a transistor switch.

12. An operation method of a memory device, comprising:
providing a plurality of page buffers coupled in series;
configuring a plurality of first switches to respectively correspond to the plurality of page buffers, such that each of the plurality of first switches is coupled to a sensing node of the corresponding page buffer; and
enabling each of the plurality of first switches to provide a source current to the sensing node of the corresponding page buffer according to a received reference voltage after a data sensing period.

13. The operation method according to claim 12, wherein the step of providing the plurality of page buffers coupled in series comprises:
providing a plurality of second switches, and enabling each of the plurality of second switches to be coupled between two adjacent page buffers among the plurality of page buffers.

14. The operation method according to claim 12, wherein the step of enabling each of the plurality of first switches to provide the source current to the sensing node of the corresponding page buffer according to the received reference voltage after the data sensing period comprises:
enabling each of the plurality of first switches to provide the source current to charge the sensing node according to a control voltage based on the reference voltage after the data sensing period.

15. The operation method according to claim 14, wherein after the data sensing period, a voltage value of the control voltage is equal to a threshold conducting voltage value of the first switch.

16. The operation method according to claim 12, further comprising:
enabling the first switch of at least one unselected buffer among the plurality of page buffers to provide the source current to charge the sensing node after the data sensing period, in order to maintain a voltage on the sensing node at a reference voltage value.

17. The operation method according to claim 12, further comprising:
enabling the first switch of at least one selected buffer among the plurality of page buffers to provide the source current to charge the sensing node after the data sensing period, in order to maintain a voltage on the sensing node at a sensed voltage value.

18. The operation method according to claim 12, further comprising:
during a compensation period following the data sensing period, enabling the first switch of each of the plurality of page buffers to begin to be turned-on, and provide the source current to the sensing node of the corresponding page buffer.

19. The operation method according to claim 18, further comprising:
in a data transfer period following the compensation period, enabling a clock signal to be pulled down from a first voltage value to a second voltage value, thereby enabling a data to be transferred from the sensing node to a latch circuit group; and
enabling the first switch of each of the plurality of page buffers to remain in a conductive state during the data transfer period.
